(19) United States
(12) Patent Application Publication
(10) Pub. No.: US 2013/0153022 A1
(43) Pub. Date: Jun. 20, 2013

(54) PHOTOELECTRIC CONVERSION DEVICE AND METHOD FOR MANUFACTURING THE SAME

(71) Applicant: SANYO Electric Co., Ltd., Osaka (JP)

(72) Inventors: Azumi UMEDA, Osaka (JP); Shigeo YATA, Ogaki-shi (JP)

(73) Assignee: SANYO Electric Co., Ltd., Osaka (JP)

(21) Appl. No.: 13/768,291

(22) Filed: Feb. 15, 2013

Related U.S. Application Data
(63) Continuation of application No. PCT/JP2011/079002, filed on Dec. 15, 2011.

(30) Foreign Application Priority Data
Dec. 17, 2010 (JP) 2010-281206

(51) Int. Cl. H01L 31/0224; H01L 31/18; H01L 31/06

(52) U.S. Cl. CPC H01L 31/022483; H01L 31/06; H01L 31/1884
USPC 136/256; 204/192.17

(57) ABSTRACT

The electric power generation efficiency of a photoelectric conversion device is improved by reducing an absorption loss of light at a back-surface electrode layer. The photoelectric conversion device includes photoelectric conversion units that convert light into electricity, a first zinc oxide layer (40a) formed on the photoelectric conversion units, a second zinc oxide layer (40b) which is formed on the first zinc oxide layer (40a) and to which aluminum and silicon are added, and a reflective metal layer (40c) formed on the second zinc oxide layer (40b).

### CROSS-REFERENCE TO RELATED APPLICATIONS

The present application is a continuation application of International Application No. PCT/JP2011/079002, filed Dec. 15, 2011, the entire contents of which are incorporated herein by reference and priority to which is hereby claimed. The PCT/JP2011/079002 application claimed the benefit of the date of an earlier filed Japanese Patent Application No. 2010-281206 filed Dec. 17, 2010, the entire contents of which are incorporated herein by reference, and priority to which is hereby claimed.

### BACKGROUND

1. Technical Field

The present invention relates to a photoelectric conversion device and a method of manufacturing the same.

2. Related Art

In recent years, photoelectric conversion devices for converting light energy into electric energy have been adopted in solar photovoltaic power generation systems and the like.

As illustrated in a cross sectional view of FIG. 5, a photoelectric conversion device is formed by including a substrate 10, a transparent electrode layer 12, a first photoelectric conversion unit 14, a second photoelectric conversion unit 18, and a back-surface electrode layer 20. The substrate 10 is a glass substrate or the like having transparency. The transparent electrode layer 12 is formed on the substrate 10. The first photoelectric conversion unit formed of amorphous silicon is laminated on the transparent electrode layer 12. The second photoelectric conversion unit 18 formed of microcrystalline silicon is laminated on the first photoelectric conversion unit 14. The back-surface electrode layer 20 is laminated on the second photoelectric conversion unit 18. The back-surface electrode layer 20 has a layered structure in which a transparent conductive oxide (TCO), a reflective metal layer, and a transparent conductive oxide (TCO) are sequentially laminated. As the transparent conductive oxide (TCO), a transparent conductive oxide obtained by doping zinc oxide (ZnO) with aluminum (Al) and gallium (Ga) as impurities is used. As the reflective metal layer, a metal such as silver (Ag) and the like can be used.

Further, JP 62-295466 A and JP 6-318718 A disclose technology for enhancing properties of a photoelectric conversion device by optimizing the composition of the transparent electrode layer 12 which is disposed on the light-entering side.

### SUMMARY

### Technical Problems

The above structure, however, has a problem that due to the absorption loss of light in the transparent conductive oxide (TCO) located between the second photoconductive conversion unit 18 and the reflective metal layer of the back-surface electrode layer 20, the short-circuit current in the photoelectric conversion device decreases to thereby lower the electric power generation efficiency.

### Means for Solving the Problems

In accordance with one aspect of the present invention, there is provided a photoelectric conversion device including a photoelectric conversion unit that converts light into electricity, a first zinc oxide layer formed on the photoelectric conversion unit, a second zinc oxide layer which is formed on the first zinc oxide layer and to which aluminum and silicon are added, and a metal layer formed on the second zinc oxide layer.

According to the present invention, it is possible to enhance the electric power generation efficiency of a photoelectric conversion device by reducing an absorption loss of light at a back-surface electrode layer.

### BRIEF DESCRIPTION OF THE DRAWINGS

Preferred embodiments of the present invention will be described in detail based on the following figures, wherein:

FIG. 1 is a cross sectional view schematically illustrating a structure of a photoelectric conversion device according to a first embodiment of the invention;

FIG. 2 is a view illustrating manufacturing process steps of the photoelectric conversion device according to the first embodiment of the invention;

FIG. 3 is a cross sectional view schematically illustrating a layered structure of a back-surface electrode layer of the photoelectric conversion device according to the first embodiment of the invention;

FIG. 4 is a view illustrating wavelength dependency of the absorption coefficient of the back-surface electrode layer according to the first embodiment of the invention;

FIG. 5 is a cross sectional view schematically illustrating a structure of a conventional photoelectric conversion device;

FIG. 6 is a cross sectional view schematically illustrating a structure of a photoelectric conversion device according to a second embodiment of the invention; and

FIG. 7 is a cross sectional view for explaining a structure of a back-surface electrode layer and a filling layer according to the second embodiment of the invention.

### DETAILED DESCRIPTION

### First Embodiment

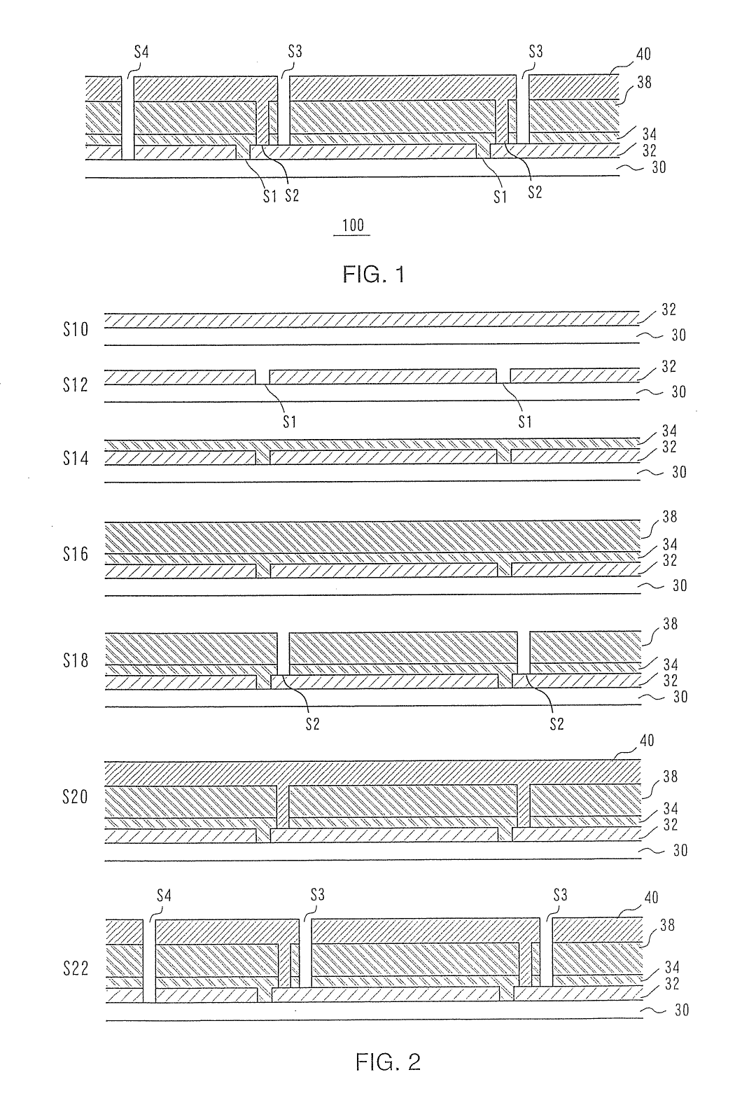

As illustrated in a cross sectional view of FIG. 1, a photoelectric conversion device 100 according to a first embodiment of the invention is configured by including a substrate 30, a transparent electrode layer 32, a first photoelectric conversion unit 34, a second photoelectric conversion unit 38, and a back-surface electrode layer 40. An intermediate layer formed of a transparent conductive film may be provided between the first photoelectric conversion unit 34 and the second photoelectric conversion unit 38.

Referring now to the manufacturing process step chart in FIG. 2, a manufacturing method of the photoelectric conversion device 100 and the structure thereof will be described. In FIGS. 1 and 2, in order to clarify the structure of the photoelectric conversion device 100, the photoelectric conversion device 100 is shown with a portion thereof being enlarged and the scale of the sections being modified.

In step S10, the transparent electrode layer 32 is formed on the substrate 30. The substrate 30 is formed of a material having transparency. In the present embodiment, a light-receiving surface of the photoelectric conversion device 100 is located on the side of the substrate 30. Here, the light-receiving surface refers to a surface which 50% or more of incident light entering the photoelectric conversion device 100 enters. The substrate 30 may be a glass substrate, a plastic substrate, or the like, for example. The transparent electrode layer 32 is a transparent conductive film having transparency. The transparent electrode layer 32 may be composed of a film made of one or a combination of a plurality of types of transparent conductive oxides (TCO) obtained by doping tin oxide (SnO₂), zinc oxide (ZnO), indium tin oxide (ITO) and the like with tin (Sn), antimony (Sb), fluorine (F), aluminum (Al), and the like. The transparent electrode layer 32 is formed by a sputtering method, a MOCVD (thermal CVD) method, and the like. It is preferable that an uneven structure (texture structure) is formed on the surface of either one or both of the substrate 30 and the transparent electrode layer 32.

In step S12, the transparent electrode layer 32 is patterned so as to form first slits S1 having a rectangular shape. The slit S1 can be formed by laser machining. For example, a YAG laser having a wavelength of 1064 nm, an energy density of 13 J/cm², and a pulse frequency of 3 kHz can be used to pattern the transparent electrode layer 32 to have rectangular slits. The line width of the slit S1 is preferably 10 μm or more and 200 μm or less.

In step S14, the first photoelectric conversion unit 34 is formed on the transparent electrode layer 32. In the present embodiment, the first photoelectric conversion unit 34 is an amorphous silicon solar cell, and is formed by laminating p-type, i-type, and n-type amorphous silicon films sequentially in this order from the substrate 30 side. The first photoelectric conversion unit 34 can be formed by plasma chemical vapor deposition (CVD), for example. As the plasma CVD, RF plasma CVD at 13.56 MHz is preferably applied. At this time, the p-type, i-type, and n-type amorphous silicon films can be laminated by forming the films by generating plasma of mixture gas obtained by mixing silicon-containing gas such as silane (SiH₄), disilane (Si₂H₆), dichlorosilane (SiH₂Cl₂), and the like; carbon-containing gas such as methane (CH₄); p-type-dopant-containing gas such as diborane (B₂H₆); n-type-dopant-containing gas such as phosphine (PH₃); and diluents gas such as hydrogen (H₂). The thickness of the i-layer of the first photoelectric conversion unit 34 is preferably 100 nm or greater and 500 nm or less.

In step S16, the second photoelectric conversion unit 38 is formed on the first photoelectric conversion unit 34. In the present embodiment, the second photoelectric conversion unit 38 is a microcrystalline silicon solar cell, and is formed by laminating p-type, i-type, and n-type microcrystalline silicon films sequentially in this order from the substrate 30 side. The second photoelectric conversion unit 38 can be formed by plasma CVD. As the plasma CVD, an RF plasma CVD at 13.56 MHz, for example, is preferably applied. The second photoelectric conversion unit 38 can be formed by generating plasma of mixture gas obtained by mixing silicon-containing gas such as silane (SiH₄), disilane (Si₂H₆), dichlorosilane (SiH₂Cl₂), and the like; carbon-containing gas such as methane (CH₄); p-type-dopant-containing gas such as diborane (B₂H₆); n-type-dopant-containing gas such as phosphine (PH₃); and diluents gas such as hydrogen (HA. The thickness of the i-layer of the second photoelectric conversion unit 38 is preferably 1000 nm or greater and 5000 nm or less.

In step S18, second slits S2 are formed by patterning in a rectangular shape. The slits S2 are formed so as to reach the transparent electrode layer 32 through the second photoelectric conversion unit 38 and the first photoelectric conversion unit 34, by laser machining, for example. The laser machining is preferably performed with the use of a laser having a wavelength of about 532 nm (the second harmonic of YAG laser), but is not limited to this example. The energy density of the laser machining may be about 1×10⁵ W/cm², for example. The slit S2 is formed by irradiation of a YAG laser at a position which is shifted in the horizontal direction from the position of the slit S1 formed in the transparent electrode layer 32 by 50 μm. The line width of the slit S2 is preferably 10 μm or greater and 200 μm or less.

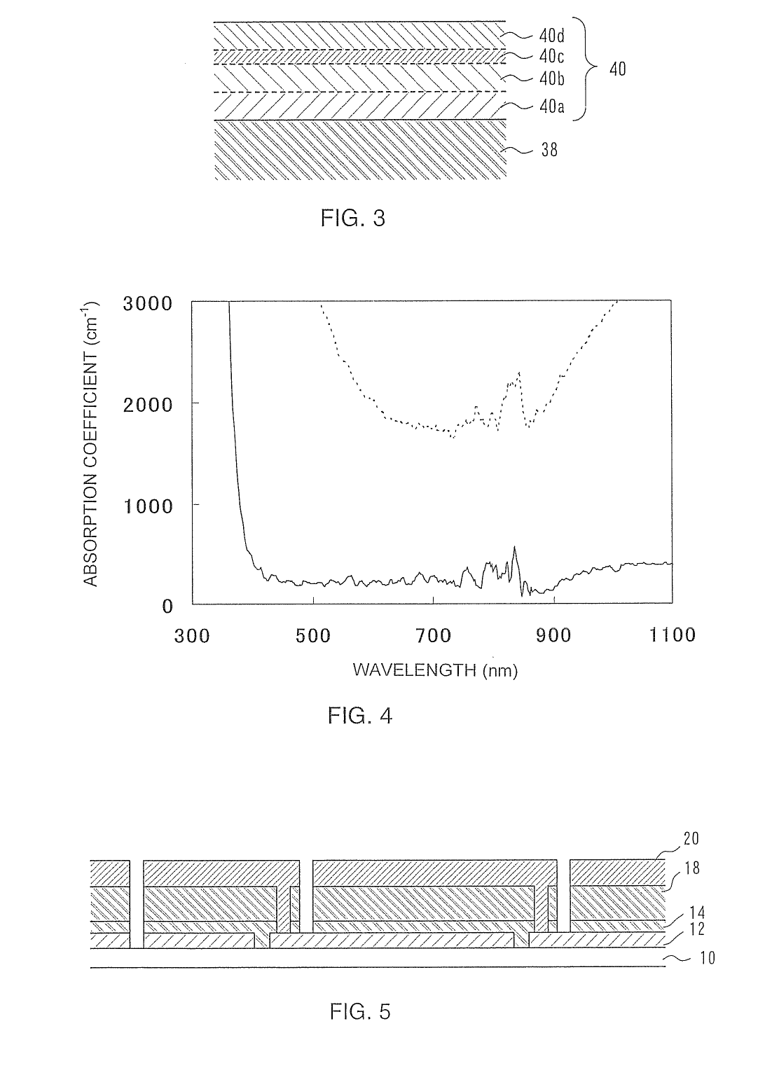

In step S20, the back-surface electrode layer 40 is formed on the second photoelectric conversion unit 38. The back-surface electrode layer 40 has a layered structure of a first zinc oxide layer 40a, a second zinc oxide layer 40b, and a third zinc oxide layer 40d, which are transparent conductive oxides (TCO), and a reflective metal layer 40c, as illustrated in an enlarged cross sectional view of FIG. 3.

As the first zinc oxide layer 40a, (AZO: Al—Zn—O) obtained by doping zinc oxide (ZnO) with aluminum (Al), or (GZO: Ga—Zn—O) obtained by doping zinc oxide (ZnO) with gallium (Ga), is applied. The first zinc oxide layer 40a is provided so as to make the electrical connection between the second photoelectric conversion unit 38 and the second zinc oxide layer 40b preferable. The first zinc oxide layer 40a can be formed by sputtering.

For example, for sputtering, a target obtained by including 2 weight percent of gallium oxide (Ga₂O₃) in zinc oxide (ZnO) is preferably used. In sputtering, electric power is supplied to argon gas at 1 W/cm² to 10 W/cm² to thereby cause the elements contained in the target to be deposited on the second photoelectric conversion unit 38.

As the second zinc oxide layer 40b, (Si-AZO: Si—Al—Zn—O) obtained by doping zinc oxide (ZnO) with aluminum (Al) and silicon (Si) is applied. The second zinc oxide layer 40b is provided so as to reduce the absorption loss of light at the transparent conductive oxides (TCO) between the second photoelectric conversion unit 38 and the reflective metal layer 40c. The second zinc oxide layer 40b can be formed by sputtering.

For example, for sputtering, a target obtained by including alumina (Al₂O₃) in an amount of 0.5 weight percent or more and 3 weight percent or less and silicon oxide (SiO₂) in an amount of 5 weight percent or more and 20 weight percent or less in zinc oxide (ZnO) is preferably used. In sputtering, electric power is supplied to argon gas or mixture gas of argon gas and oxygen gas at 1 W/cm² to 10 W/cm² to thereby cause the elements contained in the target to be deposited on the first zinc oxide layer 40a.

Here, because the elements contained in the target are deposited as the second zinc oxide layer 40b with the composition ratio of the elements remaining unchanged, the second zinc oxide layer 40b preferably includes aluminum (Al) in an amount of 0.26 weight percent or more and 1.56 weight percent or less and silicon (Si) in an amount of 2.33 weight percent or more and 9.33 weight percent or less. With such a composition ratio, the second zinc oxide layer 40b is an amorphous film. The second zinc oxide layer 40b can be measured by X-ray photoelectron spectroscopy (XPS).

Further, the total film thickness of the first zinc oxide layer 40a and the second zinc oxide layer 40b is preferably 80 nm or more and 100 nm or less. As the thickness of the first zinc oxide layer 40a is preferably 20 nm or more and 30 nm or less in order to make the electrical connection between the second photoelectric conversion unit 38 and the second zinc oxide layer 40b preferable, the film thickness of the second zinc oxide layer 40b is preferably 50 nm or more and 80 nm or less.

On the second zinc oxide layer 40b, the reflective metal layer 40c is formed. As the reflective metal layer 40c, a metal such as silver (Ag), aluminum (Al), or the like can be used. The reflective layer 40c can be formed by sputtering. For example, with the use of a target of silver (Ag) or aluminum (Al), electric power is supplied to argon gas at 1 W/cm² to 10 W/cm² to thereby cause the elements contained in the target to be deposited on the second zinc oxide layer 40b.

On the reflective metal layer 40c, the third zinc oxide layer 40d is formed as the transparent conductive oxide (TCO). As the third zinc oxide layer 40c, (AZO: Al—Zn—O) obtained by doping zinc oxide (ZnO) with aluminum (Al), or (GZO: Ga—Zn—O) obtained by doping zinc oxide (ZnO) with gallium (Ga), is applied. The third zinc oxide layer 40d can be formed by sputtering. For example, with the use of a target obtained by including 2 weight percent of gallium oxide (Ga₂O₃) in zinc oxide (ZnO), electric power is supplied to argon gas at 1 W/cm² to 10 W/cm² to thereby cause the elements contained in the target to be deposited on the reflective metal layer 40c.

The back-surface electrode layer 40 fills the slits S2 and is electrically connected with the transparent electrode layer 32 through the slits S2.

In step S22, the back-surface electrode layer 40 is patterned to form third slits S3 in a rectangular shape. The slits S3 are formed to reach the transparent electrode layer 32 through the back-surface electrode layer 40, the second photoelectric conversion unit 38, and the first photoelectric conversion unit 34. The slit S3 is formed at a location where the slit S2 is located between the slit S3 and the slit S1. The slit S3 can be formed by laser machining, by irradiating the position which is displaced from the position of the slit S2 in the horizontal direction by 50 μm with YAG laser, for example. The YAG laser having an energy density of 0.7 J/cm² and a pulse frequency of 4 kHz may be preferably used. The line width of the slit S3 is preferably 10 μm or more and 200 μm or less. Further, laser machining is performed to form a slot around the periphery of the photoelectric conversion device 100 for separating the peripheral region and the power generating region.

Further, a fourth slit S4 is formed in the peripheral portion of the substrate 30, and a slot is formed around the periphery of the photoelectric conversion device 100 for separating the peripheral region and the power generating region. The slit S4 is formed to reach the substrate 30 through the back-surface electrode layer 40, the second photoelectric conversion unit 38, the first photoelectric conversion unit 34, and the transparent electrode layer 32. The slit S4 can be formed by laser machining, preferably using a YAG laser having a wavelength of 1064 nm, an energy density of 13 J/cm², and a pulse frequency of 3 kHz. The line width of the slit S4 is preferably 10 μm or greater and 200 μm or less.

Also, a filling material and the like may be used to cover the back-surface electrode layer 40 with a back sheet for sealing. The filling material and the back sheet may be a resin material such as EVA, polyimide, and the like. Sealing can be achieved by covering the back-surface electrode layer 40 coated with the filling material with the back sheet and applying pressure onto the back sheet toward the back-surface electrode layer 40 while heating the back sheet to the temperature of about 150° C. Thus, intrusion of moisture and the like into the power generating layers of the photoelectric conversion device 100 can be further suppressed.

### EXAMPLES 1 TO 3

Table 1 indicates conditions for forming the back-surface electrode layer 40 in Examples 1 to 3. The back-surface electrode layer 40 was applied to a tandem photoelectric conversion device in which the substrate 30, the transparent electrode layer 32, the first photoelectric conversion unit 34, and the second photoelectric conversion unit 38 are formed.

In Example 1, the second zinc oxide layer 40b was formed by sputtering without introducing oxygen gas. In Example 2, the second zinc oxide layer 40b was formed by sputtering while introducing 3 sccm of oxygen gas. In Example 3, the second zinc oxide layer 40b was formed by sputtering while introducing 5 sccm of oxygen gas.

TABLE 1

| | | | FILM | INTRODUCTION | | ELECTRODE- | | | FILM |
|---|---|---|---|---|---|---|---|---|---|
| | | ELECTRIC | FORMING | GAS | | ELECTRODE | ROTATIONAL | FILM | FORMING |
| | | POWER | PRESSURE | Ar | O₂ | DISTANCE | SPEED | THICKNESS | TEMPERATURE |
| | TARGET | (W) | (Pa) | (sccm) | (sccm) | (mm) | (rpm) | (nm) | (° C.) |
| FIRST ZINC | GZO | 500 | 0.7 | 110 | 0 | 50 | 5 | 45 | 290 |
| OXIDE | | | | | | | | | |
| LAYER 40a | | | | | | | | | |
| SECOND | Si- | | 0.3 | 80 | 0, 3, 5 | | | 45 | |
| ZINC OXIDE | AZO | | | | | | | | |
| LAYER 40b | | | | | | | | | |
| REFLECTIVE | Ag | | 0.5 | 100 | 0 | | | 180 | |
| METAL | | | | | | | | | |
| LAYER 40c | | | | | | | | | |
| THIRD ZINC | GZO | | 0.7 | 110 | 0 | | | 90 | |
| OXIDE | | | | | | | | | |
| LAYER 40d | | | | | | | | | |

### COMPARATIVE EXAMPLE

Table 2 indicates conditions for forming the back-surface electrode layer 40 in Comparative Example 1 with respect to the above Examples. In this Comparative Example, the second zinc oxide layer 40b was not provided, and the first zinc oxide layer 40a, the reflective metal layer 40c, and the third zinc oxide layer 40d were laminated. In Comparative Example 1, the film thickness of the first zinc oxide layer 40a was equal to the value of the total thicknesses of the first zinc oxide layer 40a and the second zinc oxide layer 40b in Examples 1 to 3. Other conditions in Comparative Example 1 were the same as those in Examples 1 to 3.

TABLE 2

| | | | FILM | INTRODUCTION | | ELECTRODE- | | | FILM |
|---|---|---|---|---|---|---|---|---|---|
| | | ELECTRIC | FORMING | GAS | | ELECTRODE | ROTATIONAL | FILM | FORMING |
| | | POWER | PRESSURE | Ar | O₂ | DISTANCE | SPPED | THICKNESS | TEMPERATURE |
| | TARGET | (W) | (PA) | (sccm) | (sccm) | (mm) | (rpm) | (nm) | (° C.) |
| FIRST ZINC | GZO | 500 | 0.7 | 110 | 0 | 50 | 5 | 90 | 290 |
| OXIDE | | | | | | | | | |
| LAYER 40a | | | | | | | | | |
| REFLECTIVE | Ag | | 0.5 | 100 | 0 | | | 180 | |
| METAL | | | | | | | | | |
| LAYER 40c | | | | | | | | | |
| THIRD ZINC | GZO | | 0.7 | 110 | 0 | | | 90 | |
| OXIDE | | | | | | | | | |
| LAYER 40d | | | | | | | | | |

### <Properties Test>

Table 3 indicates results of measurements of photoelectric conversion properties (Open-Circuit Voltage Voc; Short-Circuit Current Isc; Fill Factor FF; Series Resistance Rs; and Conversion Efficiency Eff) concerning Examples 1 to 3 and Comparative Example 1. As indicated in Table 3, in Examples 1 to 3, the short-circuit current Isc was increased compared to that in Comparative Example 1, which resulted in an increase in the conversion efficiency Eff. It can be considered that this is because, with provision of the second zinc oxide layer 40b, the conversion efficiency in the second photoelectric conversion unit 38 was increased due to light reflected from the back-surface electrode layer 40.

TABLE 3

| | OPEN- | SHORT- | | | POWER |
|---|---|---|---|---|---|
| | CIRCUIT | CIRCUIT | FILL | SERIES | GENERATION |
| | VOLTAGE | VOLTAGE | FACTOR | RESISTANCE | EFFICIENCY |
| | (Voc) | (Isc) | (F.F.) | (Rs) | (Eff) |
| EXAMPLE 1 | 1.00 | 1.01 | 1.00 | 0.98 | 1.01 |
| EXAMPLE 1 | 0.99 | 1.02 | 0.99 | 0.99 | 1.01 |
| EXAMPLE 3 | 1.00 | 1.02 | 1.00 | 0.98 | 1.02 |
| COMPARATIVE | 1 | 1 | 1 | 1 | 1 |
| EXAMPLE 1 | | | | | |

FIG. 4 indicates results of measurements of the absorption coefficient with respect to the wavelength of light concerning a sample in which the first zinc oxide layer 40a is formed as a single film on the glass substrate and a sample in which the second zinc oxide layer 40b is formed as a single film on the glass substrate. In FIG. 4, the absorption coefficient of the first zinc oxide layer 40a is indicated by broken line and the absorption coefficient of the second zinc oxide 40b is indicated by solid line.

As indicated in FIG. 4, the absorption of the second zinc oxide layer 40b is smaller than that of the first zinc oxide layer 40a over the entire wavelength range, and is small especially at the wavelength of 850 nm or higher. Therefore, it can be assumed that with the structure in which the second zinc oxide layer 40b is disposed between the first zinc oxide layer 40a and the reflective metal layer 40c, the absorption loss of light at the back-surface electrode layer 40 can be reduced compared to the structure in which only the first zinc oxide layer 40a is provided, thereby increasing the electric power generation efficiency as a photoelectric conversion device.

Further, by providing the first zinc oxide layer 40a, electrical contact with the second photoelectric conversion unit 38 can be preferably maintained.

### Second Embodiment

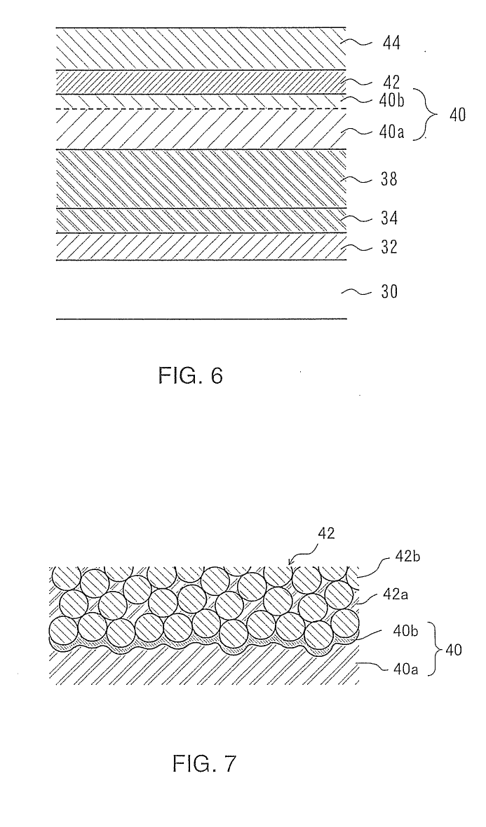

As illustrated in FIG. 6, the photoelectric conversion device 100 preferably has a structure in which the first zinc oxide layer 40a and the second zinc oxide layer 40b are laminated, and sealing is further performed with a sealing member 44 via a filling layer 42.

As illustrated in a schematic diagram of FIG. 7, the filling layer 42 includes, as a primary component, a resin 42a such as ethylene vinyl acetate (EVA) and polyvinyl butyral (PVB), in which reflective particles 42b are contained. It is preferable that the sealing member 44 is a mechanically and chemically stable material such as a glass substrate, a plastic sheet, or the like. The second zinc oxide layer 40b coated with the filling layer 42 is covered with the sealing member 44, and a pressure of about 100 kPa is applied to the sealing member 44 toward the second zinc oxide layer 40b while heating the sealing member 44 to a temperature of approximately 150° C., so that sealing can be achieved. With such sealing, it is possible to suppress intrusion of moisture or the like into the power generating layers of the photoelectric conversion device 100.

The particles 42b are formed by including a material that reflects light, and preferably includes a material that particularly reflects light having a wavelength that can transmit through the first photoelectric conversion unit 34 and the second photoelectric conversion unit 38. For example, it is preferable that the particles 42b are formed of a reflective material such as titanium oxide, silicon oxide, and the like.

In the present embodiment, as illustrated in FIG. 7, the shape of the particles 42b contained in the filling layer 42 is reflected on the light receiving surface side of the second zinc oxide layer 40b. More specifically, when sealing the back surface of the photoelectric conversion device 100 with the sealing member 44, the second zinc oxide layer 40b is press-patterned by the particles 42b contained in the filling layer 42, so that the uneven shape of the surface of the filling layer 42 formed by recesses and projections of the particles 42a is reflected on the light receiving surface side of the second zinc oxide layer 40b.

The diameter of the particles 42b is preferably set to substantially the same size as the wavelength of light which is to be reflected by the recesses and projections on the light receiving surface side of the second zinc oxide layer 40b. In the photoelectric conversion device 100 in which silicon is used in the photoelectric conversion region, the diameter of the particles 42b is preferably 200 nm or greater and 1500 nm or less. In particular, in the tandem type photoelectric conversion device 100 including the first photoelectric conversion unit 34 which is an a-Si unit and the second photoelectric conversion unit 38 which is a μc-Si unit, or a single type solar cell including only a μc-Si unit, as the wavelength of light transmitting through the second photoelectric conversion unit 38 is primarily 700 nm or more and 1200 nm or less, the diameter of the particles 42b is preferably 700 nm or more and 1200 nm or less. Further, in the case of a single type solar cell with only an a-Si unit, the diameter of the particles 42b is preferably 500 nm or more and 1000 nm or less.

Here, the diameter of the particles 42b refers to the average value of particle sizes of the particles 42b, and the average value of the particle sizes of the particles 42b observed in cross-sectional electron microscopy (SEM) or cross-sectional transmission electron microscopy (TEM) can be obtained as the average particle size. Specifically, the average particle size of the particles 42b is preferably 200 nm or more and 1500 nm or less. When a μc-Si unit is included, the particle size of 700 nm or more and 1200 nm or less is particularly preferable, and in the case of a single type solar cell with only an a-Si unit, the particle size of 500 nm or more and 1000 nm or less is particularly preferable.

The film thickness of the second zinc oxide layer 40b is made sufficiently thin so that the uneven shape formed by the particles 42b can be reflected on the light receiving surface side thereof. For example, it is preferable to set the film thickness of the first zinc oxide layer 40a to about 1.9 μm and set the film thickness of the second zinc oxide layer to about 0.1 μm. If the thickness of the first zinc oxide layer 40a is too thick, the quantity of absorption of light by the first zinc oxide layer 40a is increased to reduce the usage efficiency of light. On the other hand, if the thickness of the first zinc oxide layer 40a is too thin, conductivity as the back surface electrode layer 40 cannot be sufficiently ensured. Further, if the thickness of the second zinc oxide layer 40b is too thick, even when the second zinc oxide layer 40b is press-patterned by the particles 42b contained in the filling layer 42, the uneven shape on the surface of the filling layer 42 formed by the particles 42b cannot be reflected on the light-receiving surface side of the second zinc oxide layer 40b. On the other hand, if the thickness of the second zinc oxide layer 40b is too thin, when the second zinc oxide layer 40b is press-patterned by the particles 42b contained in the filling layer 42, the second zinc oxide layer 40b is likely to be broken, which makes it impossible to form the shape of the light receiving surface side of the second zinc oxide layer 40b so as to conform to the uneven shape on the surface of the filling layer 42 formed by the particles 42b.

With the above structure, the light that reaches the second zinc oxide layer 40b is subjected to scatter reflections by the recesses and projections on the surface of the second zinc oxide layer 40b and enters the second photoelectric conversion unit 38 and the first photoelectric conversion unit 34 once again. Specifically, due to the uneven shape on the surface of the second zinc oxide layer 40b, the quantity of reflected light and the optical path length thereof can be increased, so that the short-circuit current density Isc of the photoelectric conversion device 100 can be improved.

Further, the absorption of the second zinc oxide layer 40b is smaller than that of the first zinc oxide layer 40a over the entire wavelength range, and is particularly small at the wavelength of 850 nm or higher. Accordingly, by adopting the structure in which the second zinc oxide layer 40b is interposed between the first zinc oxide layer 40a and the filling layer 42, the loss of absorption of light in the back-surface electrode layer 40 can be suppressed compared to the structure with only the first zinc oxide layer 40a, so that the electric power generation efficiency as a photoelectric conversion device can be increased.

Also, it is preferable that the hygroscopicity of the second zinc oxide layer 40b is lower than that of the first zinc oxide layer 40a. By providing the second zinc oxide layer 40b having a lower hygroscopicity than the first zinc oxide layer 40a between the first zinc oxide layer 40a and the filling layer 42, the moisture infiltrating in the filling layer 42 finds it difficult to reach the first zinc oxide layer 40a, so that deterioration of the properties of the first zinc oxide layer 40a caused by moisture absorption can be suppressed.

While the preferred embodiments of the present invention have been described using specific terms, such description is for illustrative purposes only, and it is to be understood that changes and variations may be made without departing from the spirit or scope of the appended claims.

### REFERENCE SYMBOLS LIST

10 substrate, 12 transparent electrode layer, 14 first photoelectric conversion unit, 18 second photoelectric conversion unit, 20 back-surface electrode layer, 30 substrate, 32 transparent electrode layer, 34 first photoelectric conversion unit, 38 second photoelectric conversion unit, 30 back-surface electrode layer, 40a first zinc oxide layer, 40b second zinc oxide layer, 40c reflective metal layer, 40d third zinc oxide layer, 42 filling layer, 42a resin, 42b particle, 44 sealing member, 100 photoelectric conversion device.

1.-7. (canceled)

8. A photoelectric conversion device, comprising:
a photoelectric conversion unit that converts light into electricity;
a first zinc oxide layer that is formed on the photoelectric conversion unit;
a second zinc oxide layer that is formed on the first zinc oxide layer and to which aluminum and silicon are added; and
a metal layer that is formed on the second zinc oxide layer.

9. The photoelectric conversion device according to claim 8, wherein
the second zinc oxide layer contains the aluminum in an amount of 0.26 weight percent or more and 1.56 weight percent or less.

10. The photoelectric conversion device according to claim 8, wherein
the second zinc oxide layer contains the silicon in an amount of 2.33 weight percent or more and 9.33 weight percent or less.

11. The photoelectric conversion device according to claim 9, wherein
the second zinc oxide layer contains the silicon in an amount of 2.33 weight percent or more and 9.33 weight percent or less.

12. The photoelectric conversion device according to claim 8, wherein
the first zinc oxide layer is crystalline; and
the second zinc oxide layer is amorphous.

13. The photoelectric conversion device according to claim 9, wherein
the first zinc oxide layer is crystalline; and
the second zinc oxide layer is amorphous.

14. The photoelectric conversion device according to claim 10, wherein
the first zinc oxide layer is crystalline; and
the second zinc oxide layer is amorphous.

15. The photoelectric conversion device according to claim 8, wherein
a total film thickness of the first zinc oxide layer and the second zinc oxide layer is 80 nm or more and 100 nm or less.

16. The photoelectric conversion device according to claim 9, wherein
a total film thickness of the first zinc oxide layer and the second zinc oxide layer is 80 nm or more and 100 nm or less.

17. The photoelectric conversion device according to claim 11, wherein
a total film thickness of the first zinc oxide layer and the second zinc oxide layer is 80 nm or more and 100 nm or less.

18. The photoelectric conversion device according to claim 14, wherein
a total film thickness of the first zinc oxide layer and the second zinc oxide layer is 80 nm or more and 100 nm or less.

19. A method of manufacturing the photoelectric conversion device according to claim 8, wherein
the second zinc oxide layer is formed by sputtering of a target that contains zinc oxide (ZnO), alumina (Al₂O₃), and silicon oxide (SiO₂).

20. A method of manufacturing the photoelectric conversion device according to claim 9, wherein
the second zinc oxide layer is formed by sputtering of a target that contains zinc oxide (ZnO), alumina (Al₂O₃), and silicon oxide (SiO₂).

21. A method of manufacturing the photoelectric conversion device according to claim 11, wherein
the second zinc oxide layer is formed by sputtering of a target that contains zinc oxide (ZnO), alumina (Al₂O₃), and silicon oxide (SiO₂).

22. A method of manufacturing the photoelectric conversion device according to claim 14, wherein
the second zinc oxide layer is formed by sputtering of a target that contains zinc oxide (ZnO), alumina (Al₂O₃), and silicon oxide (SiO₂).

23. A method of manufacturing the photoelectric conversion device according to claim 18, wherein
the second zinc oxide layer is formed by sputtering of a target that contains zinc oxide (ZnO), alumina (Al₂O₃), and silicon oxide (SiO₂).

24. The method of manufacturing the photoelectric conversion device according to claim 19, wherein
the sputtering is performed by using sputtering gas containing oxygen.
